(19) United States
(12) Patent Application Publication
(10) Pub. No.: US 2024/0196628 A1
(43) Pub. Date: Jun. 13, 2024

(54) MEMORY CELLS WITH DARLINGTON PAIR BIPOLAR JUNCTION TRANSISTOR SELECTOR DEVICES

(71) Applicant: International Business Machines Corporation, Armonk, NY (US)

(72) Inventors: Alexander Reznicek, Troy, NY (US); Bahman Hekmatshoartabari, White Plains, NY (US); Praneet Adusumilli, Somerset, NJ (US); Fabio Carta, Pleasantville, NY (US)

(21) Appl. No.: 18/080,721

(22) Filed: Dec. 13, 2022

(51) Int. Cl. H10B 63/00; H10N 70/00; H10N 70/20

(52) U.S. Cl. CPC H01L 27/2445; H01L 45/06; H01L 45/16

(57) ABSTRACT

A phase change memory device or a ReRAM device is integrated with a pair of bipolar junction transistors, the pair of bipolar junction transistors being arranged in a Sziklai Darlington transistor configuration. A small unit cell footprint is obtained by pairing a vertical bipolar junction transistor with a lateral bipolar junction transistor, the memory device being electrically connected to the collector of the lateral bipolar junction transistor.

### BACKGROUND

The present disclosure relates generally to the electronic arts and, more particularly, to non-volatile memory (NVM) cells including Darlington pair bipolar junction transistor (BJT) selector devices and the fabrication of such cells.

Phase change memory (PCM) devices are among the most mature non-volatile memory options. PCM devices may include amorphous domes that can change between relatively high and low electrically conductive states. Large amorphous domes may require relatively large threshold voltages. Another mature NVM technology employs filamentary ReRAM devices for synaptic cell fabrication. Relatively large voltages (>3V) may also be required for such memory devices.

Bipolar junction transistors have been employed as selector devices for driving PCM devices. Such transistors include emitter, collector and base regions. A biasing voltage applied between a base contact and an emitter contact allows control of collector current. Bipolar junction transistors can be employed as sensors, switches, amplifiers, and for high performance and/or high voltage applications. Bipolar junction transistors can be configured as NPN or PNP transistors that include heavily doped emitters and collectors.

### BRIEF SUMMARY

Non-volatile memory cells including pairs of bipolar junction transistors and techniques for fabricating such cells are provided in accordance with one or more embodiments of the inventions discussed herein.

In one aspect, an exemplary memory cell includes a memory device and a selector device. The memory device includes phase change material. The selector device includes a lateral bipolar junction transistor including an intrinsic base, an extrinsic base, a collector region and an emitter region. The collector region of the lateral bipolar junction transistor is electrically connected to the memory device. It further includes a vertical bipolar junction transistor wherein the extrinsic base of the lateral bipolar junction transistor serves as a collector region of the vertical bipolar junction transistor. One of the lateral bipolar junction transistor and the vertical bipolar junction transistor is a PNP transistor, the other of the lateral bipolar junction transistor and the vertical bipolar junction transistor being an NPN transistor. The lateral bipolar junction transistor and the vertical bipolar junction transistor form a Sziklai Darlington transistor pair.

In a further aspect of the invention, a memory cell includes a memory device and a selector device. The memory device includes a phase change memory device or a resistive random access memory device. The selector device includes a lateral bipolar junction transistor and a vertical bipolar junction transistor configured as a Sziklai Darlington transistor pair. The lateral bipolar junction transistor includes collector that is electrically connected to the memory device.

In another aspect, an exemplary method of fabricating a memory cell includes forming a Sziklai Darlington transistor pair including a lateral bipolar junction transistor and a vertical bipolar junction transistor atop the lateral bipolar junction transistor. The lateral bipolar junction transistor includes an emitter region, a collector region, an intrinsic base region, and an extrinsic base region adjoining the intrinsic base region. The memory cell is fabricated such that the extrinsic base region of the lateral bipolar junction transistor is also a collector region of the vertical bipolar junction transistor. The method further includes forming a memory device electrically connected to the collector region of the lateral bipolar junction transistor, wherein forming the memory device includes forming a bottom electrode, a top electrode, and phase change material between the bottom electrode and the top electrode.

Techniques and devices as disclosed herein can provide substantial beneficial technical effects. Some embodiments may not have these potential advantages and these potential advantages are not necessarily required of all embodiments. By way of example only and without limitation, one or more embodiments may provide one or more of the following advantages:
Relatively small memory cell footprint;
Selectors capable of sustaining relatively large voltages for programming PCM devices;
Selectors compatible with older technology nodes;
Reasonable cost of fabrication while providing sufficient integration density.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a circuit diagram illustrating an exemplary memory cell including a PCM and a Darlington pair of bipolar junction transistors, the PCM being electrically connected to the emitter of the Darlington transistor pair that comprises the collector of a PNP bipolar junction transistor;

FIG. 1B is a circuit diagram illustrating an exemplary memory cell including a PCM and a Darlington pair of bipolar junction transistors, the PCM being electrically connected to the emitter of the Darlington transistor pair that comprises the collector of an NPN bipolar junction transistor;

FIG. 2 is a schematic, cross-sectional view showing a silicon germanium-on-insulator substrate having a p+ base layer thereon;

FIG. 3 is a schematic, cross-sectional view showing the structure of FIG. 2 following patterning of the p+ base layer and vertical spacer formation;

FIG. 4 is a schematic, cross-sectional view of the structure of FIG. 3 following vertical recessing the silicon germanium layer of the substrate and showing ion implantation of the silicon germanium layer;

FIG. 5 is a schematic, cross-sectional view of the structure of FIG. 4 following growth of emitter and collector regions, deposition of an interlevel dielectric layer, and chemical mechanical planarization;

FIG. 6 is a schematic, cross-sectional view thereof following further planarization to expose the p+ base layer and formation of a bottom spacer;

FIG. 7 is a schematic, cross-sectional view of the structure of FIG. 6 following deposition of a layer of sacrificial material, a top spacer, and an oxide layer;

FIG. 8 is a schematic, cross-sectional view showing the structure shown in FIG. 7 following formation of a trench down to the bottom spacer and oxidation of exposed surfaces of the layer of sacrificial material;

FIG. 9 is a schematic, cross-sectional view of the structure shown in FIG. 8 following formation of an opening in the bottom spacer;

FIG. 10 is a schematic, cross-sectional view following epitaxial growth of base material on the base layer of the structure shown in FIG. 9 and polishing epitaxial overgrowth down to the top surface of the oxide layer;

FIG. 11 is a schematic, cross-sectional view following deposition of additional oxide material and deposition and patterning of a hardmask on the structure shown in FIG. 10;

FIG. 12 is a schematic, cross-sectional view thereof following removal of exposed oxide material, exposed portions of the top spacer, and portions of the layer of sacrificial material, and;

FIG. 13 is a schematic, cross-sectional view following removal of the remaining portions of the layer of sacrificial material;

FIG. 14 is a schematic, cross-sectional view of the structure shown in FIG. 13 following removal of the oxidized portions of the layer of sacrificial material and epitaxial growth of further base material;

FIG. 15 is a schematic, cross-sectional view of the structure shown in FIG. 14 following replacement of the existing hard mask with a new hard mask;

FIG. 16 is a schematic, cross-sectional view of the structure shown in FIG. 15 following recessing unprotected portions of the further base material;

FIG. 17 is a schematic, cross-sectional view of the structure shown in FIG. 16 following deposition of interlevel dielectric material, removal of the new hard mask, and planarization;

FIG. 18 is a schematic, cross-sectional view of the structure shown in FIG. 17 following deposition and patterning of a further hard mask and recessing the oxide layer and base material;

FIG. 19 is a schematic, cross-sectional view of the structure shown in FIG. 18 following epitaxial growth of emitter material on the base material and removal of the further hard mask;

FIG. 20 is a schematic, cross-sectional view of the structure shown in FIG. 19 following formation of a metal contact that electrically contacts the collector of a planar bipolar junction transistor;

FIG. 21 is a schematic, cross-sectional view of the structure shown in FIG. 20 following formation of a bottom electrode on the metal contact;

FIG. 22 is a schematic, cross-sectional view of the structure shown in FIG. 21 following deposition and patterning of a tetraethyl orthosilicate (TEOS) layer, deposition of phase change material, and planarization;

FIG. 23 is a schematic, cross-sectional view of the structure shown in FIG. 22 following top electrode formation over the phase change material;

FIG. 24 is a schematic, cross-sectional view of a phase change memory cell in accordance with one exemplary embodiment following further contact formation within the structure shown in FIG. 23;

FIG. 25 is a schematic, cross-sectional view of a partially completed phase change memory cell including a contact opening, a metal contact electrically connected to the collector of a bottom bipolar junction transistor, and partial metal fill within the contact opening to form a bottom electrode;

FIG. 26 is a schematic, cross-sectional view of the structure shown in FIG. 25 following widening of the contact opening and deposition of phase change material on the bottom electrode;

FIG. 27 is a schematic, cross-sectional view a phase change memory cell in accordance with a further embodiment following formation of a top electrode and further contacts within the structure shown in FIG. 26;

FIG. 28 is a schematic, cross-sectional view of a phase change memory cell in accordance with a further embodiment, including a Sziklai Darlington transistor pair and a confined cell phase change memory structure; and

FIG. 29 is a schematic, cross-sectional view of a phase change memory cell in accordance with a further embodiment, including a Sziklai Darlington transistor pair and a “mushroom” cell phase change memory structure.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the inventions discussed herein will be described herein in the context of illustrative memory cells including bipolar junction transistor selector devices fabricated on a silicon substrate. It is to be appreciated, however, that the specific embodiments and/or methods illustratively shown and described herein are to be considered exemplary as opposed to limiting. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Relatively large voltages may be required for operation of non-volatile memory devices such as phase change memory (PCM) and filamentary ReRAM devices. The threshold voltage of PCM devices may also increase over time due to resistance drift, thereby increasing the desirability of larger programming voltages. PCM devices including relatively large amorphous domes may require large threshold voltages and large programming currents. The use of multiple FETs to program PCMs can result in a larger FET footprint which increases the footprint of the synaptic unit cell. As described below with respect to the illustrative embodiments, relatively compact selector devices can provide relatively large voltages and currents, thereby reducing unit cell sizes and increasing computational density. The inventions as described herein also have application to older technology nodes (e.g. 45 nm, 32 nm, 22 nm) that reduce cost of technology and are readily practiced for embedded memory fabrication. As many emerging memory technologies are embedded at older CMOS FEOL (front-end-of-line) nodes, selectors compatible with such nodes allow reduced fabrication costs while still providing sufficient integration density.

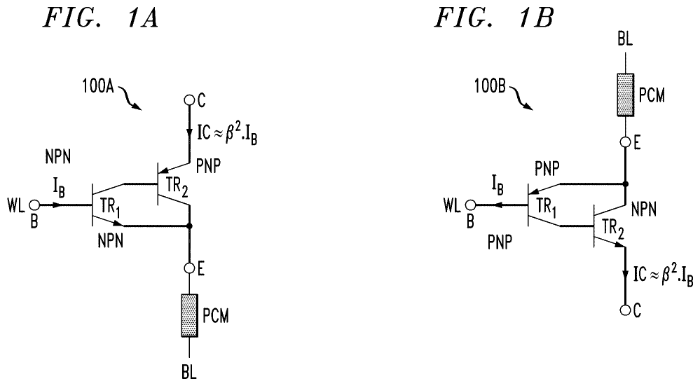

A Sziklai Darlington transistor configuration includes a pair of transistors wherein the collector current of a first bipolar transistor (TR1) in the pair is equal to the base current of the second bipolar transistor (TR2) of the pair. The overall gain of the pair of transistors is approximately the product of the gains of the two transistors TR1, TR2. The turn-on voltage of the Sziklai Darlington pair is the same as that of the first transistor TR1. The Sziklai Darlington transistor pair is a complementary or compound Darlington device that includes separate NPN and PNP complementary transistors connected together, as shown in the exemplary circuit diagrams depicted in FIG. 1A and FIG. 1B. The terms “Darlington pair”, “Darlington transistor pair” and “Sziklai Darlington transistor pair” as employed herein relate to the complementary or compound Darlington device having the Sziklai Darlington transistor configuration.

FIG. 1A and FIG. 1B are circuit diagrams of two alternative embodiments of the invention that depict Sziklai Darlington transistor pairs for driving a PCM device. In the exemplary embodiment shown in FIG. 1A, the emitter and collector of the first bipolar transistor TR1 within the circuit 100A are formed of n-type conductivity material while the base is formed of p-type conductivity material; the transistor TR1 is accordingly considered an NPN device. The emitter and collector of the transistor TR2 are formed of a p-type conductivity material and the base formed of an n-type conductivity material, thereby resulting in a PNP BJT device. The emitter and collector are symmetric in some embodiments. In a symmetric lateral (planar) device, the collector is as heavily doped as the emitter. The quasi-neutral base width is smaller than the physical emitter-collector separation by the depletion layers from both the emitter and collector sides. In accordance with one or more embodiments of the invention, the transistor pairs include a lateral/planar BJT (transistor TR2 in FIG. 1A and FIG. 1B) and a vertical BJT (transistor TR1 in FIG. 1A and FIG. 1B) atop the lateral BJT; the lateral BJT's extrinsic base also serves as the collector of the vertical BJT. With reference to FIG. 1A, the element labelled “C” is the collector of the Darlington transistor pair and the emitter of the lateral transistor TR2. The element “E” is the emitter of the Darlington transistor pair, the emitter of the vertical transistor TR1, and the collector of the lateral transistor TR2.

In the circuit 100B illustrated in FIG. 1B, the first (vertical) transistor TR1 is a PNP device while the second (lateral) transistor TR2, having the opposite polarity, is an NPN device. The collector current of TR1 is equal to the base current of TR2. The element “E” in the circuit 100B is the emitter of the Darlington transistor pair, the emitter of the transistor TR1, and the collector of transistor TR2. The element “C” thereof is the collector of the Sziklai Darlington transistor pair and the emitter of the transistor TR2. Write and read operations can be performed using the word line WL and the bit line BL. The overall gain of the Sziklai Darlington transistor pair is approximately the product of the gains of the two BJTs, namely Ic≈β²IB. In one or more exemplary embodiments, the selector devices within each circuit 100A, 100B are configured to sustain voltages greater than 3.5V and current up to 1 mA for programming PCM devices. The PCM cell connected in series with the selector devices (TR1, TR2) can, for example, be a “mushroom” type PCM, a confined cell PCM, or a pore cell PCM. A ReRAM (resistive random access memory) device (not shown) can be integrated in series with the pair of BJT devices in some alternative embodiments.

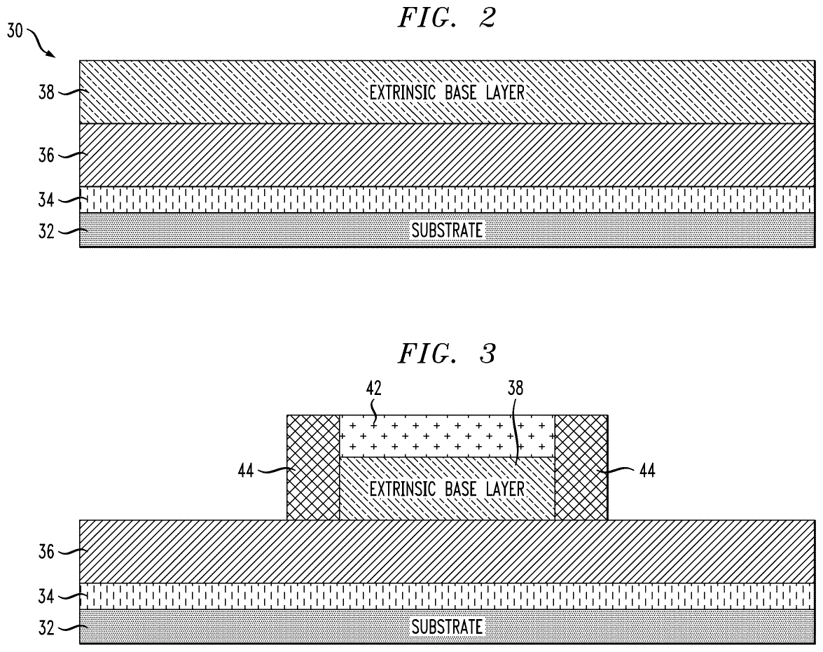

FIG. 2 through FIG. 24 schematically illustrate an exemplary process for fabricating a phase change memory cell in accordance with a first embodiment of the invention. A vertical BJT is formed over a planar (lateral) BJT, thereby allowing a reduced cell footprint. A PCM device is electrically connected to the collector of the planar BJT to complete the phase change memory cell. Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. While some individual processing steps are set forth herein, those steps are merely illustrative, and one skilled in the art may be familiar with several equally suitable alternatives that would be applicable.

With reference now to FIG. 2, a layered structure 30 includes a semiconductor-on-insulator (SOI) substrate wherein a buried dielectric layer 34 (i.e., buried oxide or BOX layer) or a punch through stop (PTS) region separates a (base) semiconductor substrate 32 from a top semiconductor layer 36. In other embodiments, a bulk semiconductor substrate can be used in the fabrication process. In this exemplary embodiment, the top semiconductor layer 36 is a silicon-germanium layer wherein the buried dielectric layer 34 electrically isolates the top semiconductor layer from the semiconductor substrate 32. The semiconductor substrate may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide. In the exemplary embodiment, the semiconductor substrate 32 is made of single-crystalline silicon (Si). The semiconductor substrate 32 may, for example, be approximately several hundred microns thick. In some embodiments, the semiconductor substrate 32 may include a thickness varying from approximately 600 micrometers to approximately 1,000 micrometers, and ranges therebetween.

The buried dielectric layer 34 (i.e., BOX layer) may be formed from any of several known dielectric materials or combinations thereof. Non-limiting examples include oxides, nitrides and oxynitrides of silicon. Oxides, nitrides and oxynitrides of other elements are also envisioned. In addition, the buried dielectric layer may include crystalline or non-crystalline dielectric material. The buried dielectric layer 34 may be formed using any of several known methods. Non-limiting examples include ion implantation methods, thermal or plasma oxidation or nitridation methods, chemical vapor deposition methods and physical vapor deposition methods. In accordance with an exemplary embodiment, the buried dielectric layer 34 may include a thickness varying from approximately 20 nm to approximately 200 nm, and ranges therebetween.

The top semiconductor layer 36 in one exemplary embodiment is a silicon-germanium (SiGe) layer. In one exemplary embodiment, the top semiconductor layer includes a single-crystalline SiGe layer with a 20% germanium concentration. Methods for forming the top semiconductor layer 36 are well known in the art. Non-limiting examples include wafer bonding or thermal mixing. The top semiconductor layer 36 may include a thickness varying from approximately 6 nm to approximately 100 nm, and ranges therebetween. The conductivity type of the top semiconductor layer, which later forms an intrinsic base of a lateral bipolar junction transistor, is determined by the type of transistor (NPN or PNP) to be fabricated.

The multi-layer structure 30 depicted in FIG. 2 further includes an extrinsic base layer 38 that is epitaxially grown on the top semiconductor layer 36. The terms “epitaxially growing and/or depositing” and “epitaxially grown and/or deposited” mean the growth of a semiconductor material on a deposition surface of a semiconductor material in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

In some embodiments, the gas source for the deposition of epitaxial semiconductor material includes a silicon-containing gas source, a germanium containing gas source, or a combination thereof. For example, an epitaxial silicon (Si) layer can be deposited from a silicon gas source that is selected from the group consisting of silane, disilane, trisilane, tetrasilane, hexachlorodisilane, tetrachlorosilane, dichlorosilane, trichlorosilane, and combinations thereof. An epitaxial germanium layer can be deposited from a germanium gas source that is selected from the group consisting of germane, digermane, halogermane, dichlorogermane, trichlorogermane, tetrachlorogermane and combinations thereof. An epitaxial silicon-germanium layer can be formed utilizing a combination of the aforementioned gas sources. Carrier gases like hydrogen, nitrogen, helium and argon can be used. In an exemplary embodiment, the extrinsic base layer 38 is an epitaxially grown single-crystalline silicon or silicon germanium layer. In one or more preferred embodiments, the extrinsic base layer 38 is comprised of a material having a wider band gap than that of the intrinsic base material. For example, if the intrinsic base layer 36 is comprised of silicon or silicon germanium, the extrinsic base layer 38 is comprised of silicon. If the intrinsic base and the extrinsic base layers are both comprised of silicon germanium, the silicon content of the extrinsic base layer 38 is greater than that of the intrinsic base layer.

In embodiments wherein the lateral BJT to be formed is an NPN transistor, the top semiconductor (intrinsic base) layer 36 and the extrinsic base layer 38 grown thereon will have p-type conductivity. Both layers will have n-type conductivity if a PNP lateral transistor is to be formed. As used herein, the term “conductivity type” denotes a dopant region being p-type or n-type. As used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contributes free electrons to an intrinsic semiconductor. In a silicon-containing substrate, examples of n-type dopants, i.e., impurities, include but are not limited to antimony, arsenic and phosphorous. The dopants may be incorporated in situ using appropriate precursors, as known in the art. By “in-situ” it is meant that the dopant that dictates the conductivity type of a doped layer is introduced during the process step, e.g., epitaxial deposition, that forms the doped layer. In one exemplary embodiment, the heavily doped extrinsic base layer 38 has a doping concentration of 5×10¹⁹ cm⁻³ or greater and the top semiconductor (intrinsic base) layer 36 has a lesser doping concentration of 1×10¹⁹ cm⁻³ or smaller.

Referring to FIG. 3, a hard mask 42 is deposited and patterned on the extrinsic base layer 38. The hard mask can include a dielectric material such as silicon dioxide, silicon nitride, silicon carbide, and the like, and can be deposited by any suitable deposition method known in the art. The process of patterning the extrinsic base layer 204 may include steps well-known in the art, which generally include forming a pattern on a photoresist layer (not shown) that is transferred to the hard mask layer 42 and used to pattern the underlying extrinsic base layer 38 via any suitable etching technique.

Subsequent to the patterning process, spacer material can be deposited on the resulting structure and subsequently etched to form sidewall spacers 44 as shown in FIG. 3. The hard mask of the structure may have a thickness between approximately 50 nm to approximately 150 nm, although other thicknesses above or below this range may be used as desired for a particular application. The spacer material forming the sidewalls spacers 44 may include an electrically insulating material such as an oxide, nitride, oxynitride, silicon carbon oxynitride, silicon boron oxynitride, low-k dielectric, or any combination thereof. Standard deposition and etching techniques may be used to form the sidewalls spacers 44. For example, the spacer material can be etched using an anisotropic etch to form the sidewall spacers. The spacer material is removed from all horizontal surfaces of the structure during the etching process, leaving the vertically oriented sidewall spacers 44 on the side walls of the hard mask and the extrinsic base layer. Sidewall spacer width may be between approximately six (6) nm to approximately twelve (12) nm, although other thicknesses above or below this range may be used as desired for a particular application.

Referring to FIG. 4, a cross-sectional view of the structure after recessing the top semiconductor layer 36 is shown. Known etching techniques can be applied to recess the top semiconductor layer 36 down to the top surface of the BOX layer 34. In an exemplary embodiment, a reactive ion etching (RIE) process can be used to recess the top semiconductor layer 36. The width of the top semiconductor layer 36 is equal to the combined widths of the extrinsic base layer 38 and sidewall spacers 44. The sidewall surfaces of the top semiconductor (intrinsic base) layer 36 are accordingly coplanar with outer surfaces of the sidewall spacers 44.

Referring again to FIG. 4, an optional ion implantation process is shown according to an exemplary embodiment. The ion implantation process is conducted prior to forming emitter and collector regions of the lateral BJT. As known by those skilled in the art, BJTs are three-terminal electronic devices that include three semiconductor regions, namely an emitter, a base, and a collector. Generally, a BJT includes a pair of p-n junctions, namely a collector-base junction and an emitter-base junction. A voltage applied across the emitter-base junction of a BJT controls the movement of charge carriers that produce charge flow between the collector and emitter regions of the BJT.

Angled ion implantation is optionally conducted on opposing sides of the recessed top semiconductor layer 36, as depicted in the figure by arrows. The ion implantation process, if employed, provides counter-doping of the intrinsic base layer formed by the top semiconductor layer 36. As mentioned above, embodiments of the present disclosure are illustrated using an NPN bipolar junction transistor that includes two regions of n-type semiconductor material and a region of p-type semiconductor material located between the two regions of n-type semiconductor material. In this embodiment, since an exemplary NPN bipolar junction transistor is being formed, n-type dopants such as arsenic or phosphorous are implanted within the surface portions under the spacers 44 of the p-type SiGe (intrinsic base) layer 36 using a hot ion implantation process. In alternative embodiments for forming PNP bipolar junction transistors, angled ion implantation of p-type dopants such boron fluoride (BF₂) into an n-type intrinsic base layer may be performed. A dopant concentration of p-type dopants (e.g., boron) may vary from approximately 1×10¹⁸ ions/cm³ to approximately 9×10²⁰ ions/cm³, while a dopant concentration of n-type dopants (i.e., arsenic or phosphorus) may vary from approximately 1×10¹⁸ ions/cm³ to approximately 9×10²⁰ ions/cm³.

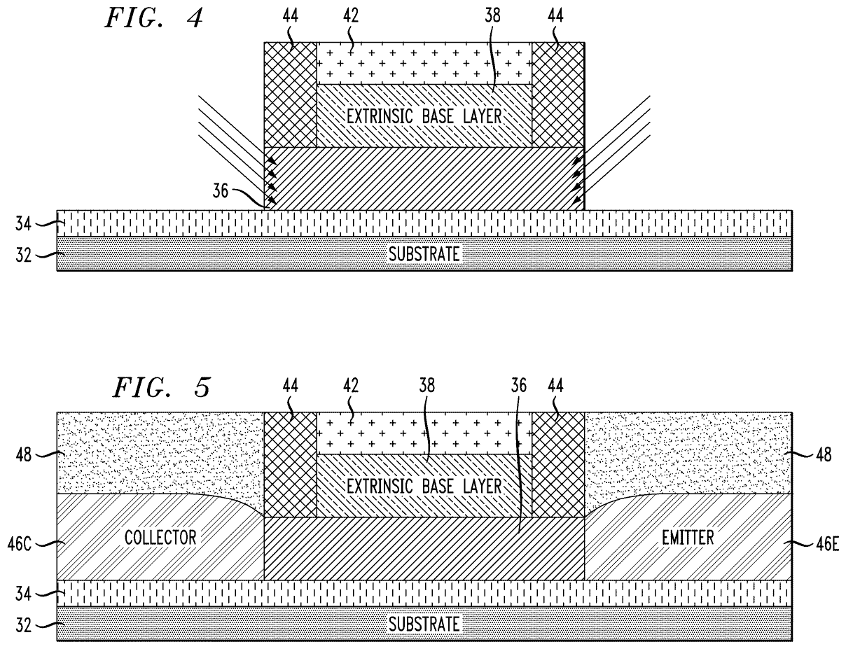

Referring to FIG. 5, a cross-sectional view of the structure is shown after forming emitter and collector regions of a lateral bipolar junction transistor and deposition of an interlevel dielectric layer. The emitter region 46E and the collector region 46C can be formed by, for example, epitaxial growth of an in-situ doped single-crystalline Si or SiGe layer on the exposed vertical surfaces of the top semiconductor (intrinsic base) layer 36. In some embodiments, the emitter region 46E and the collector region 46C may include a material similar to that forming the intrinsic base region (i.e., the recessed top semiconductor layer 36), but with a slightly higher bandgap. In one exemplary embodiment, silicon emitter and collector regions are grown on the side walls of a silicon germanium layer. Epitaxial materials forming the emitter region and the collector region can be grown from gaseous or liquid precursors using low pressure chemical vapor deposition (LPCVD), plasma enhanced chemical vapor deposition (PECVD), atmospheric pressure chemical vapor deposition (APCVD), vapor-phase epitaxy (VPE), molecular-beam epitaxy (MBE), liquid-phase epitaxy (LPE), or other suitable process. Epitaxial silicon, silicon germanium, germanium, and/or carbon doped silicon (Si: C) can be doped during deposition (in-situ doped) by adding n-type dopants (e.g., phosphorus or arsenic) or p-type dopants (e.g., boron or gallium), depending on the type of transistor to be fabricated at this stage of the process. The emitter and collector are symmetric in some embodiments.

An interlevel dielectric (ILD) layer 48 is deposited on the resulting structure and planarized down to the top surface of the hard mask 42. The ILD layer may be formed by, for example, chemical vapor deposition (CVD) of a dielectric material. Non-limiting examples of dielectric materials to form the ILD layer may include silicon oxide, silicon nitride, hydrogenated silicon carbon oxide, silicon based low-k dielectrics, flowable oxides, porous dielectrics, or organic dielectrics including porous organic dielectrics. Chemical mechanical planarization (CMP) techniques can be employed for planarizing the ILD layer. In one exemplary embodiment, an n+ emitter, an n+ collector and a p-type base comprise a lateral NPN bipolar junction transistor that forms part of a Sziklai Darlington transistor pair, as described further below.

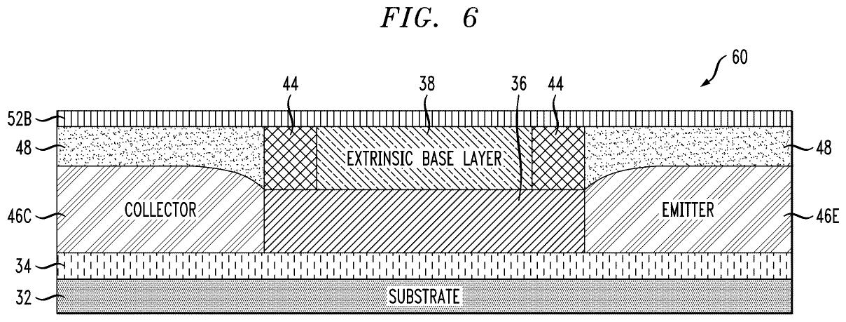

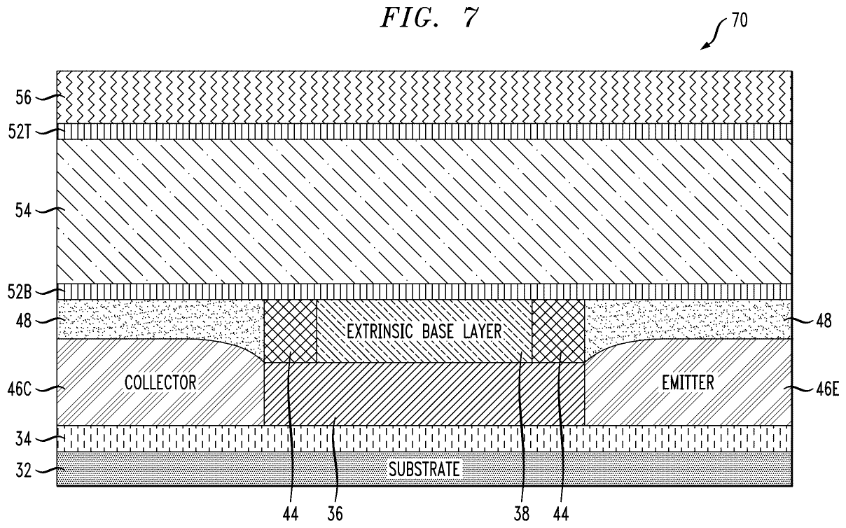

Further planarization that exposes the top surface of the extrinsic base layer 38 is performed. This step is followed by formation of a blanket layer forming a horizontal bottom spacer 52B over the underlying lateral BJT. The bottom spacer may comprise silicon nitride or other suitable dielectric material. A structure 60 as schematically illustrated in FIG. 6 may be obtained.

A sacrificial layer 54 is formed over the bottom spacer 52B and planarized. The sacrificial layer 54 may be an amorphous silicon (a-Si) or a polycrystalline silicon (polysilicon) layer. The sacrificial material may be deposited by a deposition process such as, but not limited to, physical vapor deposition (PVD), chemical vapor deposition (CVD), plasma enhanced chemical vapor deposition (PECVD), inductively coupled plasma chemical vapor deposition (ICP CVD), or any combination thereof. Hydrogenated amorphous silicon is typically deposited by plasma-enhanced chemical vapor deposition (PECVD) although other techniques such as hot-wire chemical vapor deposition (HWCVD) may be used. A top spacer 52T is formed on the top surface of the sacrificial layer 54. The top and bottom spacers are both silicon nitride spacers in some embodiments. Referring to the structure 70 shown in FIG. 7, an oxide (for example, silicon oxide) layer 56 is formed over the top spacer 52T.

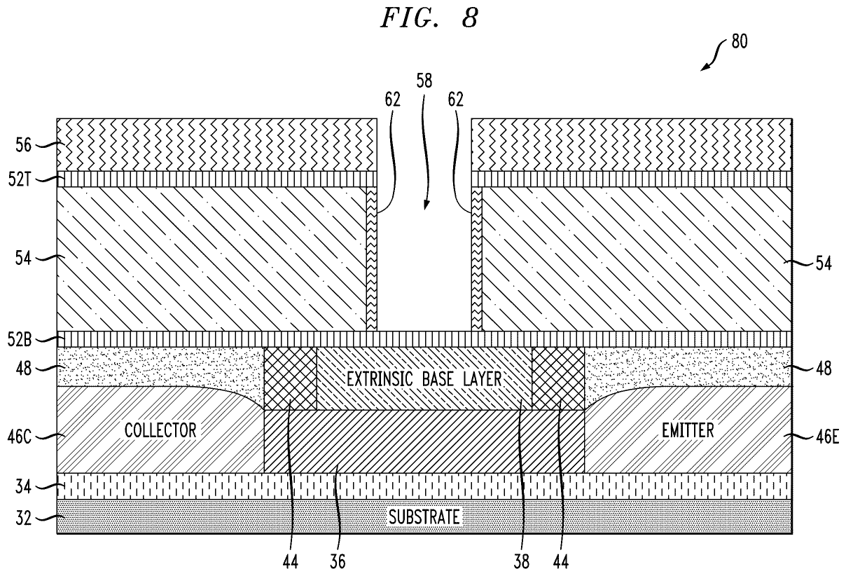

The oxide layer 56, the top spacer 52T and the sacrificial layer 54 are subjected to directional etches to form a trench 58 extending down to the top surface of the bottom spacer 52B. As shown in FIG. 8, the width of the trench 58 is smaller than the width of the extrinsic base layer of the lateral BJT as viewed in the depicted cross-section. The exposed portions of the sacrificial layer 54 adjoining the trench are oxidized to form thin oxide layers 62 extending vertically between the bottom and top spacers. Plasma oxidation or any other suitable oxidation technique may be employed to form the thin oxide layers 62 on the surfaces of sacrificial layer 54. A structure 80 as shown in FIG. 8 is thereby obtained.

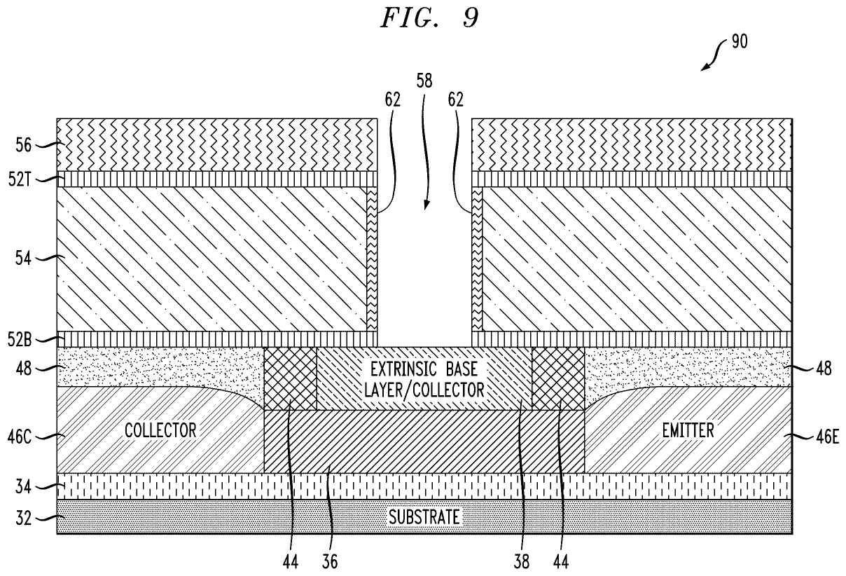

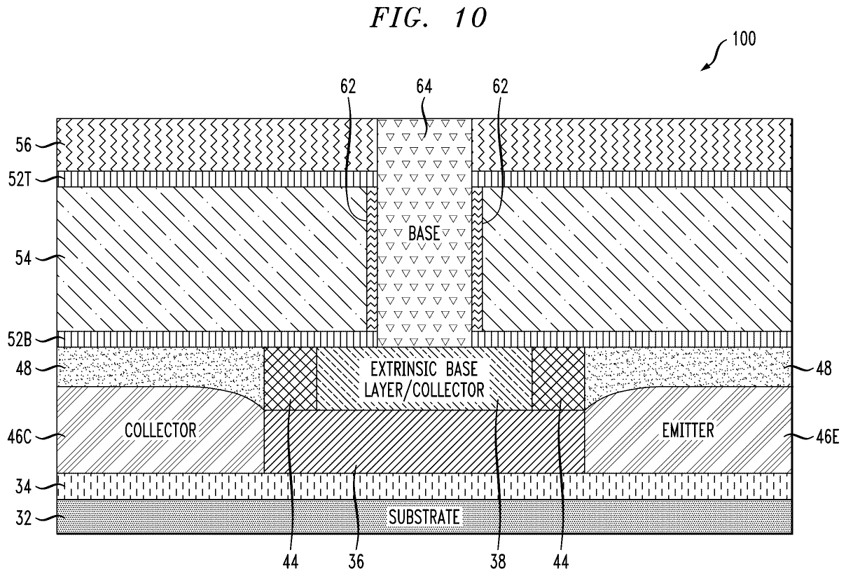

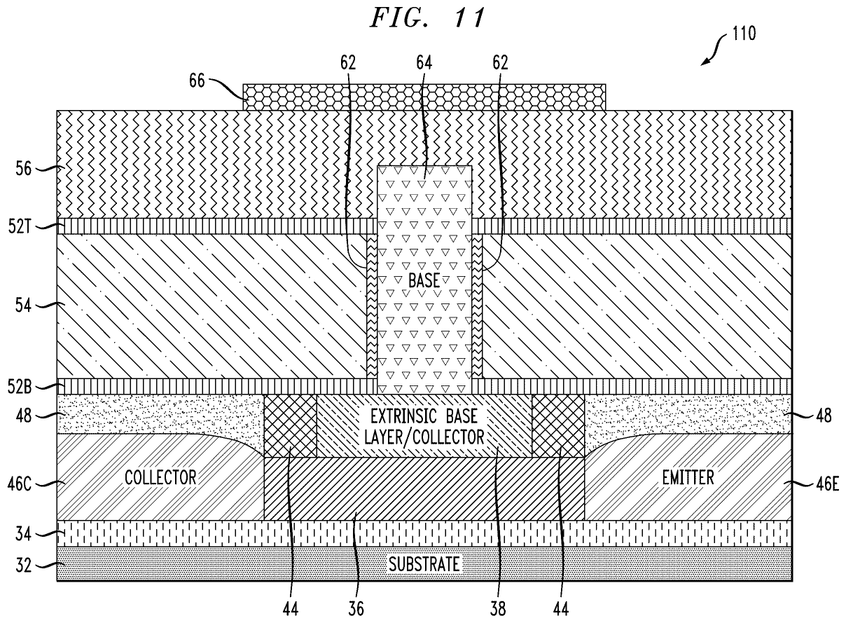

Referring to the structure 90 shown in FIG. 9, the portion of the bottom spacer 52B at the bottom of the trench 58 is selectively removed. The top surface of the extrinsic base layer 38 is exposed at the bottom of the trench 58 following such. The extrinsic base layer 38 of the lateral BJT formed beneath the bottom spacer 52B also forms the collector of a vertical BJT that is completed as described below. This layer is accordingly shown and described as an extrinsic base/collector in one or more embodiments, including the processing stage shown in FIG. 9 and subsequent figures.

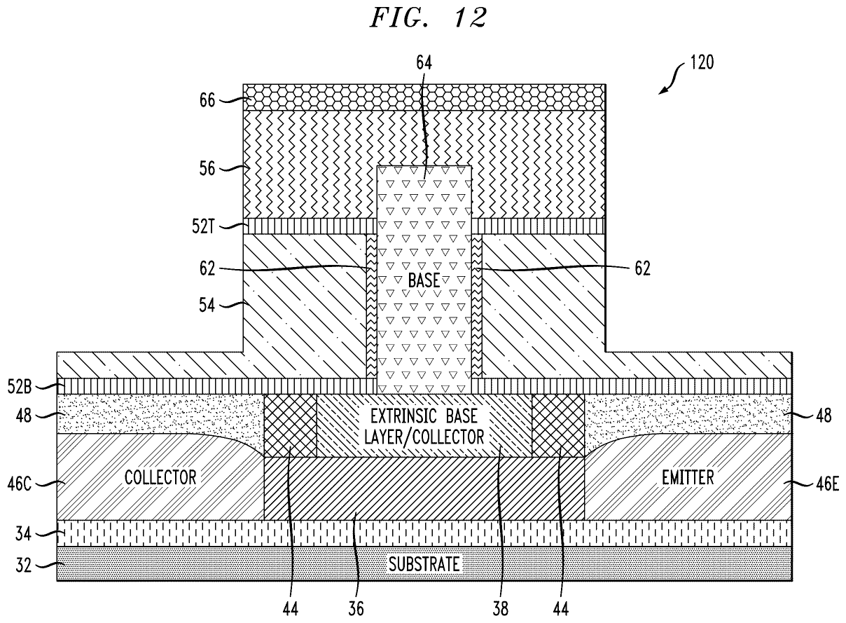

Base material for a vertical BJT is epitaxially grown on the top surface of the highly doped extrinsic base layer/collector 38. The base material for the vertical BJT should be lattice matched or close to lattice matched to the lattice of the emitter region 46E of the planar BJT to avoid excessive strain leading to structural defects in the intrinsic base for the vertical BJT. Overgrowth of the base material is polished down to the top surface of the oxide layer 56. A structure 100 as shown in FIG. 10 may be obtained. The base epitaxy 64 (e.g. silicon epitaxy) extends from the top surface of the extrinsic base/collector 38 to the top surface of the oxide layer 56. The sidewalls of the base epitaxy are bounded by the thin oxide layers 62 and end portions of the top and bottom spacers at this stage of the fabrication process. The conductivity type of the base epitaxy 64 is opposite to that of the extrinsic base/collector 38.

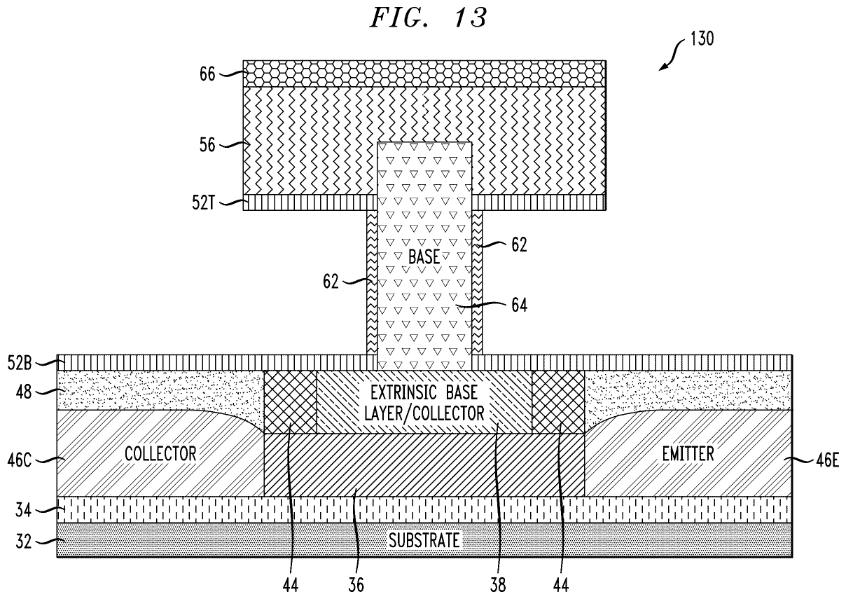

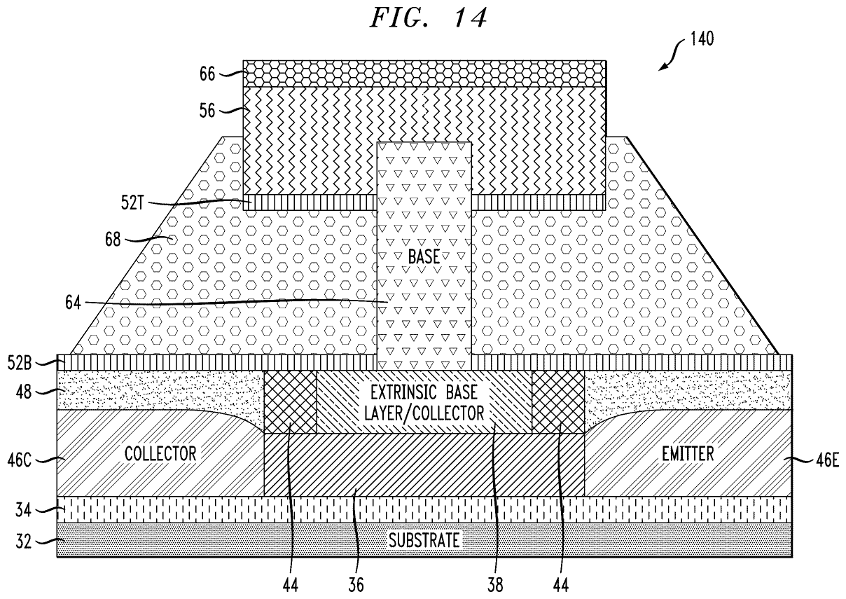

Referring to FIG. 11, a hard mask 66 is deposited and patterned on the top surface of the oxide layer 56. The hard mask extends over the base epitaxy 64 and also overlaps portions of the sacrificial layer 54 on each side of the base epitaxy. The structure 110 shown in FIG. 11 is subjected to a reactive ion etch through exposed portions of the oxide layer, the top spacer 52T and the sacrificial layer 54. The etch is timed such that the bottom spacer 52B remains covered by a portion of the sacrificial layer. As shown in FIG. 12, the layers beneath the hard mask 66 remain intact in the resulting structure 120 following the reactive ion etch.

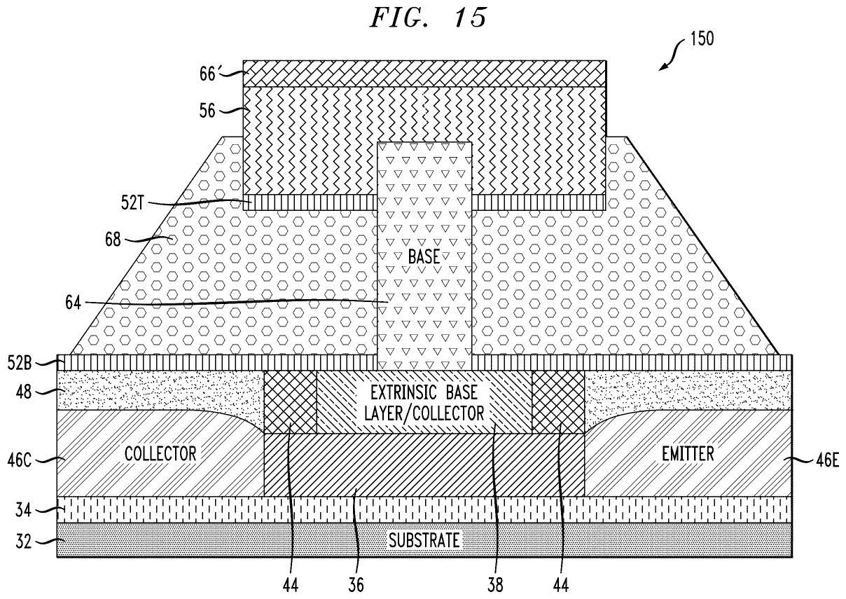

Referring to FIG. 13, the sacrificial layer 54 is selectively removed to obtain a structure 130 wherein the thin oxide layers 62 on the side walls of the base epitaxy 64 are exposed. The thin oxide layers 62 are then removed using, for example, a short hydrofluoric acid (HF) etch or a SiCoNi™ vapor phase etch process. A SiCoNi™ etch is a plasma-assisted dry etch process that involves simultaneous exposure of a substrate to hydrogen, NF₃ and NH₃ plasma by-products using processing equipment available from Applied Materials, Inc. Vertical surfaces of the base epitaxy 64 between the top and bottom spacers 44 are exposed following oxide removal.

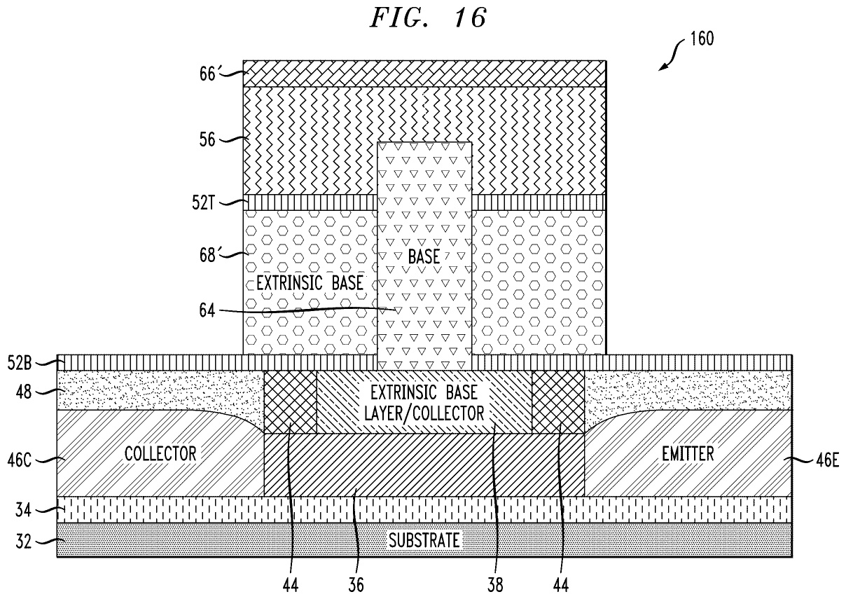

Base material extensions 68 used in forming a doped (e.g. n+ SiGe) extrinsic base are grown on the side walls of the base epitaxy 64 to obtain a structure 140 as schematically illustrated in FIG. 14. The extension epitaxy may or may not be defective (large grain polycrystalline) epitaxy. Defects in the extensions 68, if any, will not propagate into the base epitaxy. The configurations of the base material extensions shown in FIG. 14 are exemplary and may have different configurations in other embodiments. The doped base material extensions 68 extend completely around the base epitaxy 64 that forms the intrinsic base of a vertical BJT.

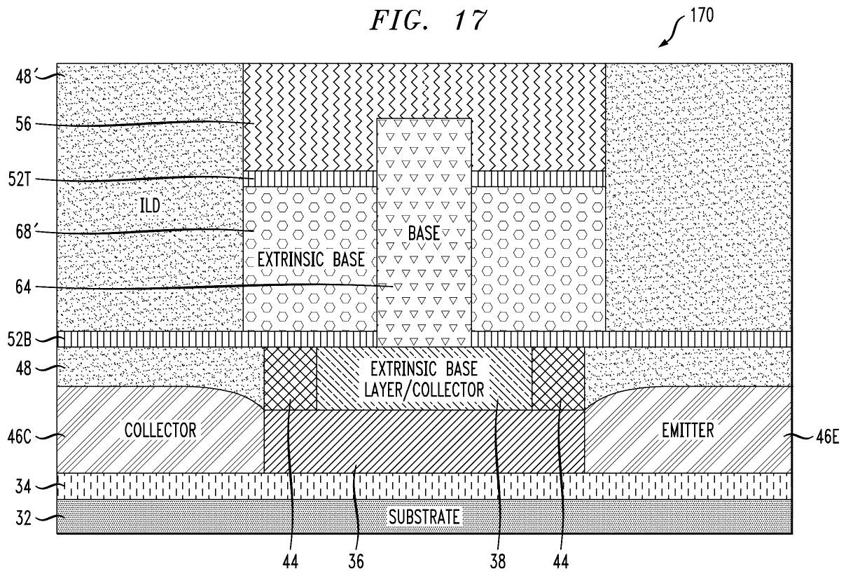

The hard mask 66 on the oxide layer is replaced by a new hard mask 66′ to obtain a structure 150 as schematically illustrated in FIG. 15. In addition to allowing recessing of the base material extensions in the plane shown in cross-section in the figure, it is further patterned to allow the left and right sides of the base material extensions to be electrically isolated.

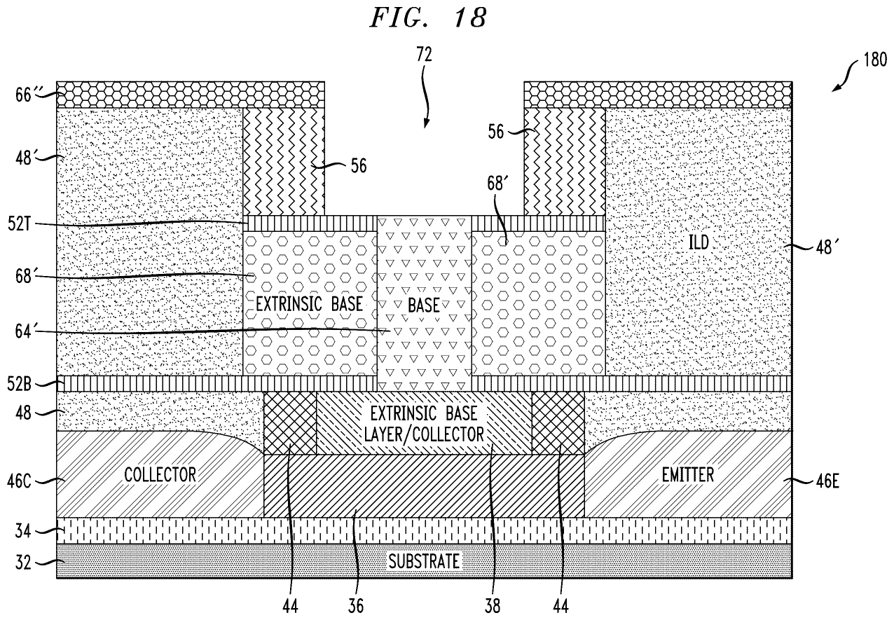

Referring to FIG. 16, the doped base material extensions 68 are recessed using the new hard mask 66′ to form the extrinsic base 68′ of a vertical BJT that is completed later in the process. The doped base material is recessed in the plane shown in cross section as well as outside the drawing plane to electrically isolate the left side of the extrinsic base 68′ from the right side thereof. The extrinsic base 68′ of the resulting structure 160 adjoins the intrinsic base epitaxy and overlaps portions of the underlying lateral BJT. The bottom spacer 52B provides electrical isolation between the extrinsic base 68′ of the top (vertical) BJT and the extrinsic base/collector 38.

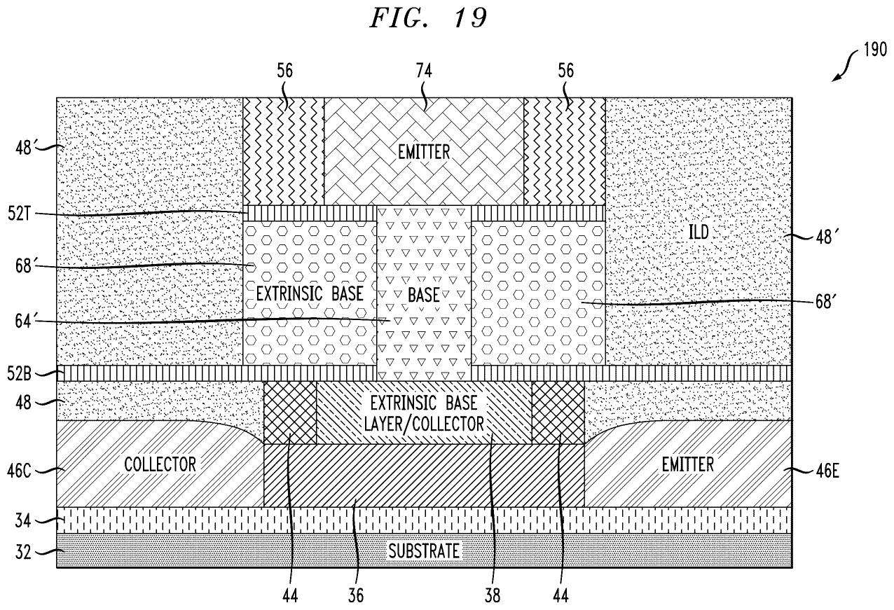

A further ILD layer 44′ is deposited on the structure 160 and fills the recesses therein. Following removal of the hard mask 66′ used to recess the doped base material, the structure is subjected to chemical mechanical planarization to obtain a structure 170 as shown in FIG. 17.

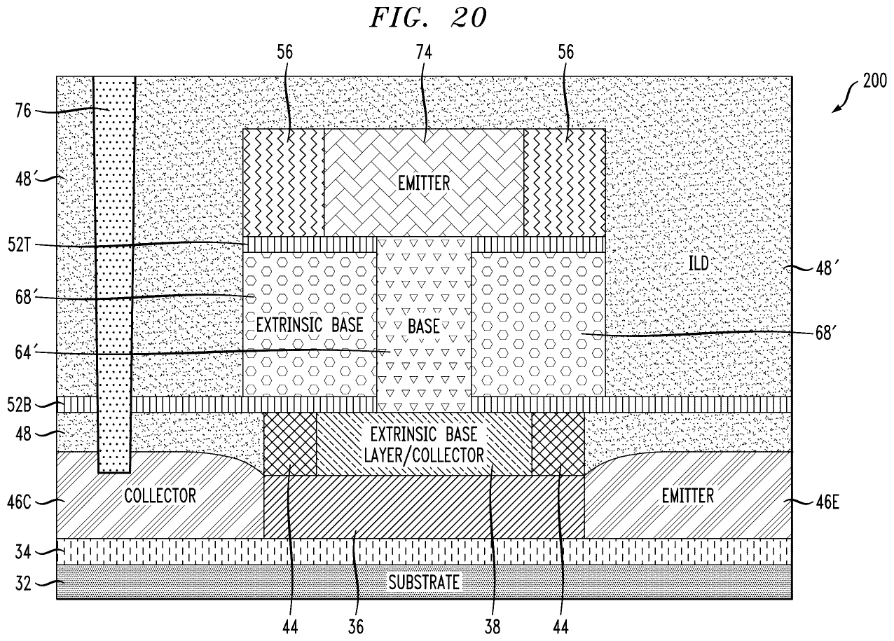

A further hard mask 66″ is deposited on the structure 170 and patterned to facilitate forming the emitter region of the vertical bipolar junction transistor. Referring to FIG. 18, the oxide layer 56 and the (intrinsic) base epitaxy 64 are recessed down to the top spacer 52T. The top surface of the intrinsic base 64′ formed from the base epitaxy is thereby exposed at the bottom of the recess 72 within the resulting structure 180.

An emitter 74 is epitaxially grown on the top surface of the intrinsic base 64′, thereby completing fabrication of a vertical bipolar junction transistor directly above the lateral bipolar junction transistor formed earlier in the process. In the exemplary structure 190 depicted in FIG. 19, the emitter may or may not be a large grain polycrystalline structure (defective epitaxy). As discussed above with respect to the growth of the extrinsic base epitaxy on the sidewalls of the base epitaxy, defects within the emitter also will not propagate into the base epitaxy forming the intrinsic base 64′ of the vertical BJT. The emitter 74 is highly doped (e.g. p+ SiGe) and thereby forms part of a vertical PNP bipolar junction transistor, the p+ extrinsic base of the underlying lateral BJT also forming the collector of the vertical BJT. The hard mask 66″ is removed and the structure is then optionally planarized. The resulting structure 190 accordingly includes an NPN lateral BJT and a PNP vertical BJT directly over the lateral BJT. It will be appreciated that the techniques described herein can be easily modified to provide an alternative structure including a PNP lateral BJT and an NPN vertical BJT.

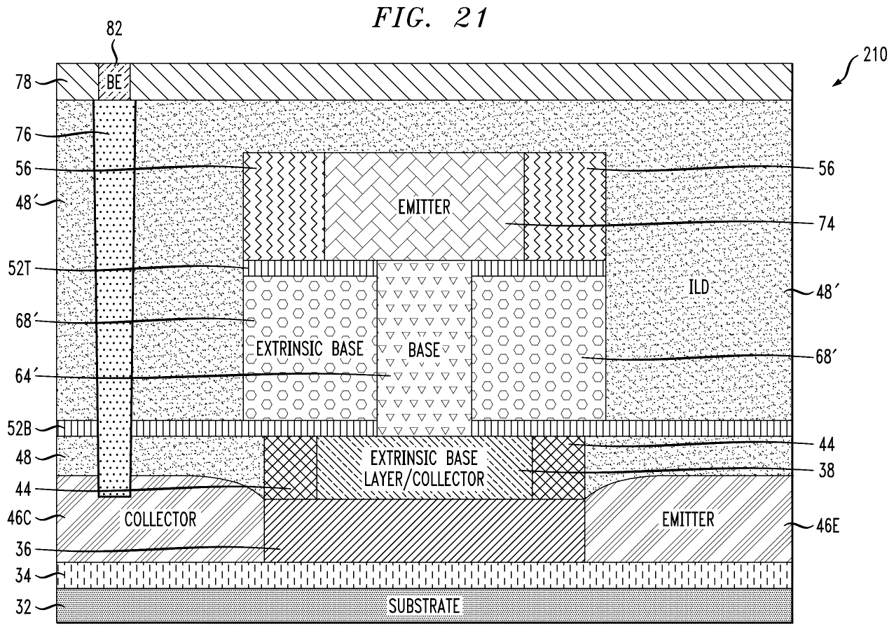

Further ILD fill material is deposited on the structure 190 and planarized. A contact opening is formed through the top ILD layer 48′, the bottom spacer 52B, the bottom ILD layer 48, and extending into the collector 46C of the lateral BJT. (As discussed above, the collector 46C of the lateral BJT is also the emitter of the Darlington transistor pair.) A metal silicide or metal germano-silicide layer (not shown) may be formed on the collector 46C. Contact metal is then deposited, filling the contact opening. The contact metal may include a barrier liner. Metal overburden can be removed from the structure using a chemical mechanical planarization process. A structure 200 is obtained wherein a metal contact 76 extends from the collector 46C of the lateral BJT to the top surface of the structure. FIG. 20 provides a cross-sectional view of the structure 200 following formation of the Darlington transistor pair emitter contact 76.

A dielectric layer 78 is deposited on the top surface of the structure. The dielectric layer may, for example, comprise silicon nitride or a low-k silicon carbonitride material such as NBLOK™. The latter material comprises Si, C, O, H, and N, is marketed by Applied Materials, Inc., and can be deposited using PECVD. An opening is formed in the dielectric layer 78 directly above the top surface of the contact 76. A typical phase change memory (PCM) device may include a layer of phase change material sandwiched between a bottom electrode and a top electrode. The bottom electrode 82 of a PCM device is formed on the contact 76 within the opening formed in the dielectric layer 78. FIG. 21 illustrates an exemplary structure 210 at this stage of the process.

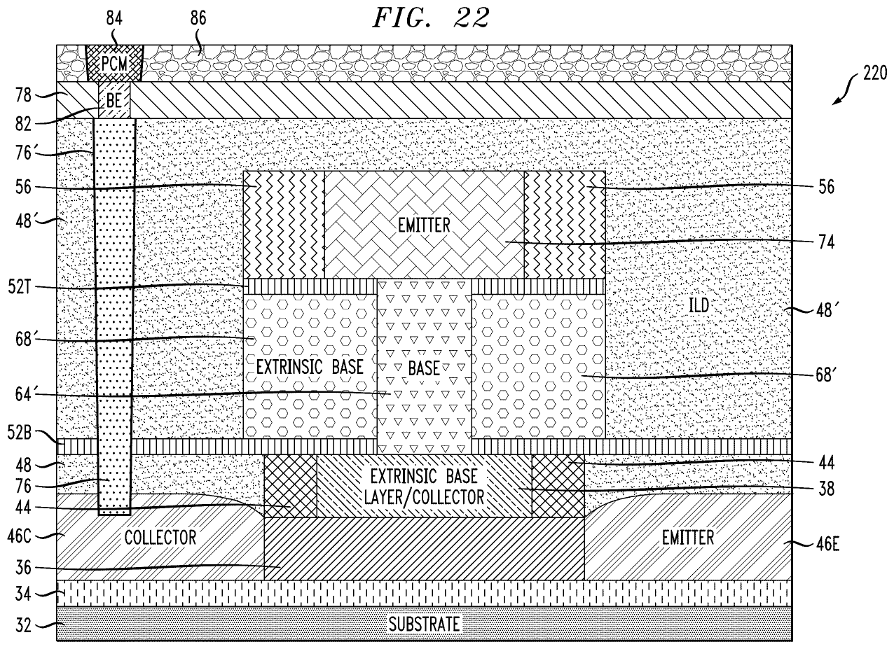

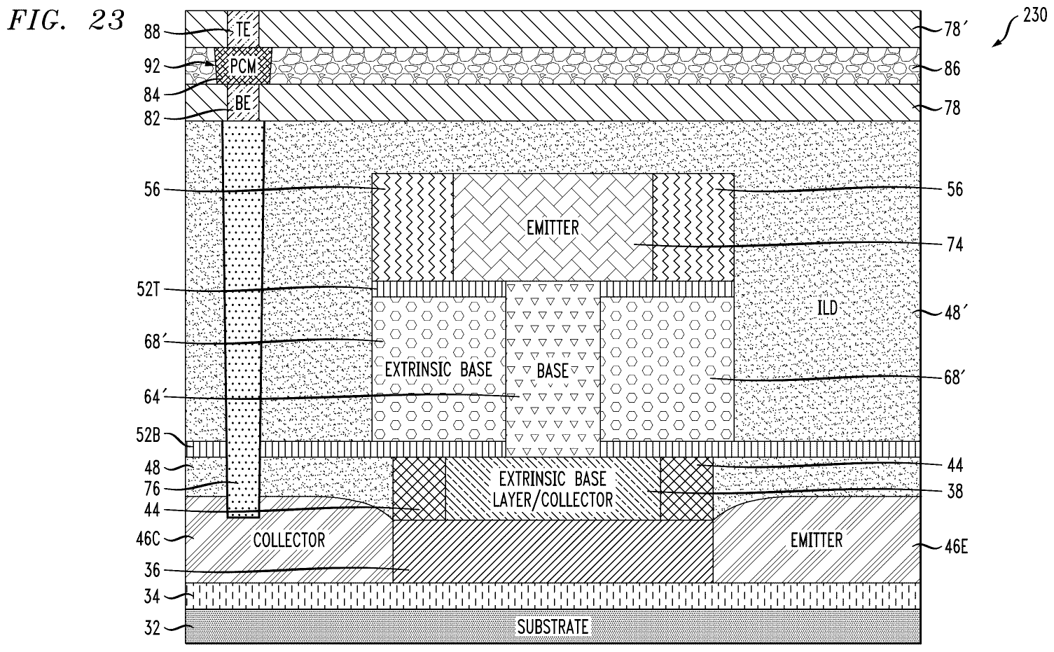

Referring to FIG. 22, phase change material 84 such as GeSbTe (germanium-antimony-tellurium or GST) is deposited on the bottom electrode (BE) 82. A second dielectric layer 86 such as tetraethyl orthosilicate (TEOS) may be deposited using PECVD on the dielectric layer 78 containing the bottom electrode 82 and patterned. The phase change alloy comprising chalcogen elements such as GST is deposited on the structure, filling an opening within the further dielectric layer 86 directly above the bottom electrode 82. The resulting structure may be planarized to obtain a structure 220 as shown in FIG. 22.

A top electrode 88 is formed on the phase change material 84 to complete a PCM device 92. A third dielectric layer 78′ is deposited on the second dielectric layer 86 and patterned to form an opening directly above the phase change material 84. The third or top dielectric layer 78′ may comprise the same material as the first dielectric layer 78 formed on the ILD layer 48′. The top electrode 88 fills the opening in the top dielectric layer 78′ and contacts the phase change material 84. The PCM device includes the top and bottom electrodes 88, 82 and the phase change material 84 therebetween. The PCM device 92 is electrically connected by the metal contact 76 to the collector 46C of the lateral bipolar junction transistor within the structure, as exemplified by the structure 230 shown in FIG. 23.

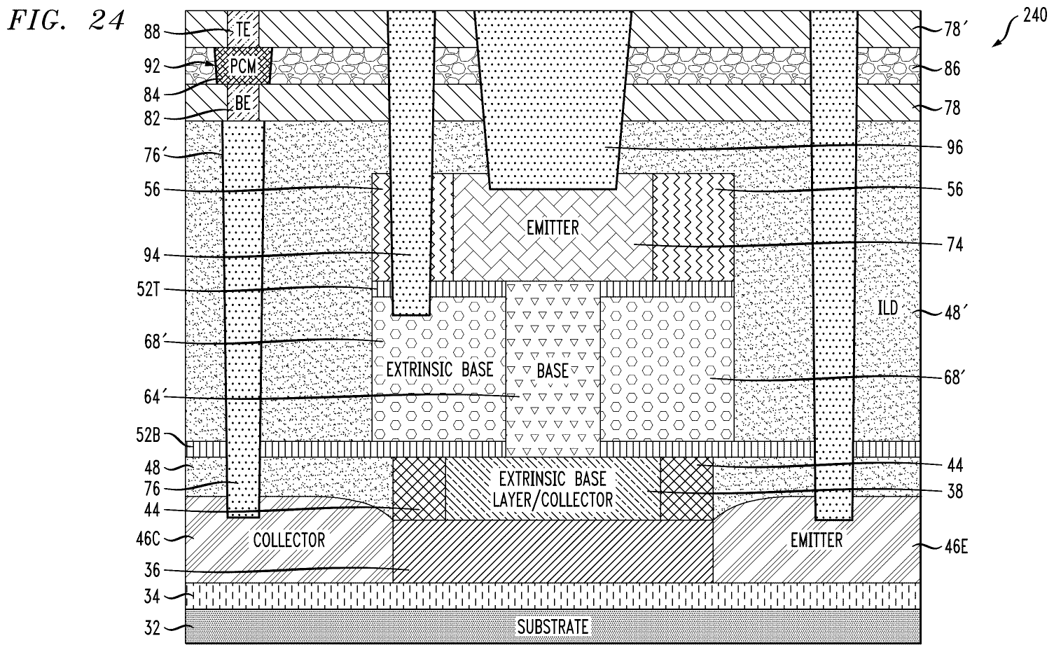

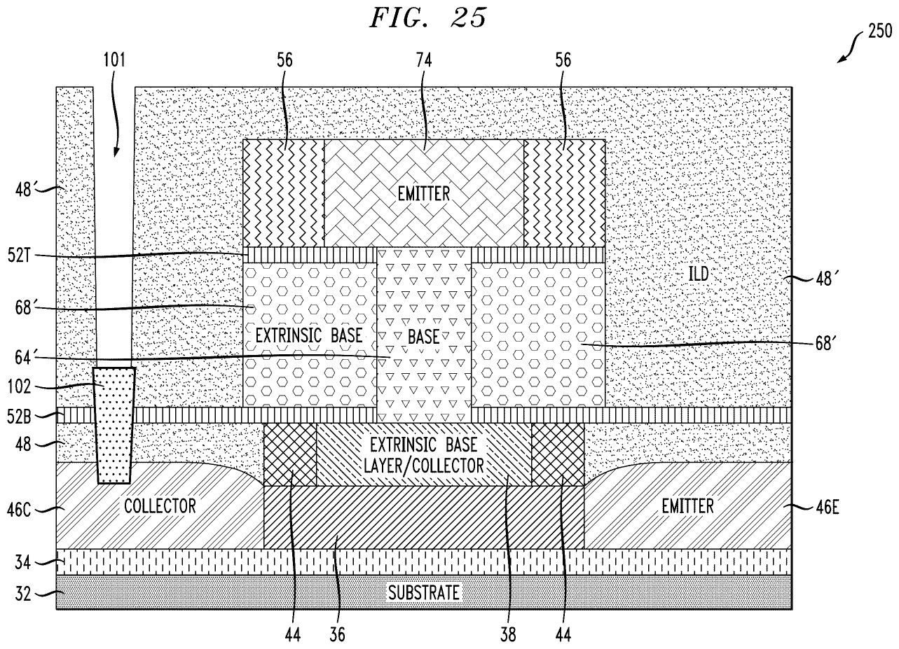

A first exemplary embodiment of a phase change memory cell 240 including a Sziklai Darlington transistor pair selector is schematically illustrated in FIG. 24. Metal contacts 94, 96, 98 are formed in the structure 230. Metal overburden is removed to obtain the memory cell 240. The metal contacts are in contact, respectively, with the highly doped extrinsic base 68′ of the vertical BJT, the emitter 74 of the vertical BJT, and the emitter 46E of the lateral BJT. The top electrode 88 of the PCM device 92 is electrically connected (not shown in FIG. 24) to the bit line (BL). The circuitry of the memory cell 240 can correspond to that shown in either FIG. 1A or FIG. 1B depending on the polarities (NPN or PNP) of the BJTs therein. The formation of a vertical BJT directly above a lateral BJT allows a relatively small unit cell footprint. The Sziklai Darlington transistor pair selector can, in one or more embodiments, sustain voltages exceeding 3.5V and current up to 1 mA for programming PCM devices. A Sziklai Darlington pair of transistors can drive a PCM device the same way as a single NPN BJT or PNP BJT, but with an effectively much higher BJT gain. In alternative embodiments, a ReRAM device is integrated with the Sziklai Darlington pair rather than a PCM device.

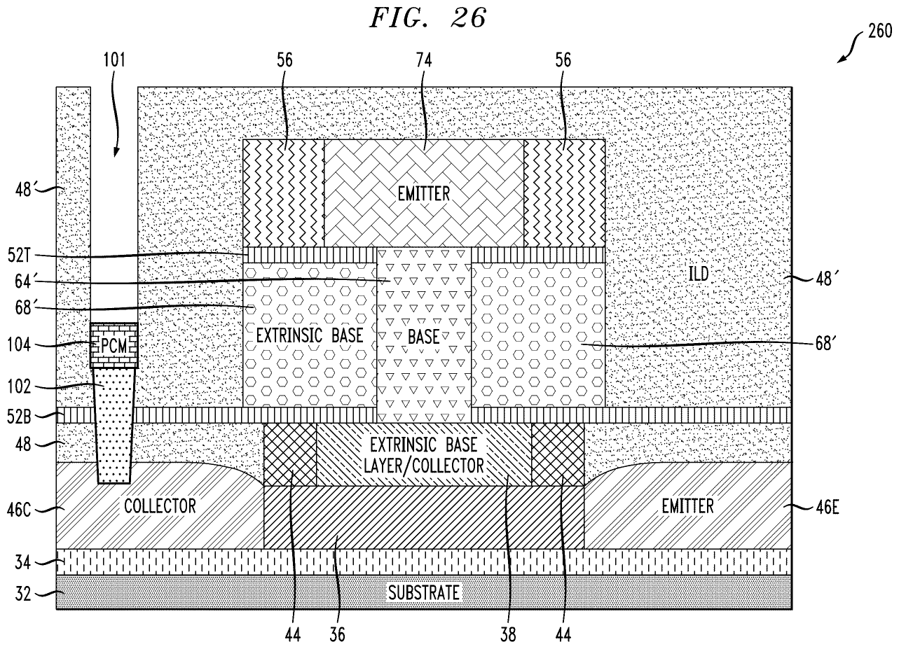

A processing stage of a further embodiment is schematically illustrated in FIG. 25. The same reference numerals as employed above are used in this figure to designate the same or similar elements. A contact opening 101 is formed through the structure 250 down to the collector 46C of the lateral BJT of a Sziklai Darlington pair of bipolar junction transistors that further includes a vertical BJT. Following formation of a metal silicide layer (not shown) on the collector 46C, the contact opening is partially filled with a metal such as tantalum nitride (TaN) or titanium nitride (TIN). The deposited metal is electrically connected to the collector 46C of the lateral BJT and forms a bottom electrode 102. The bottom electrode of a PCM device is also commonly described as a “heater.”

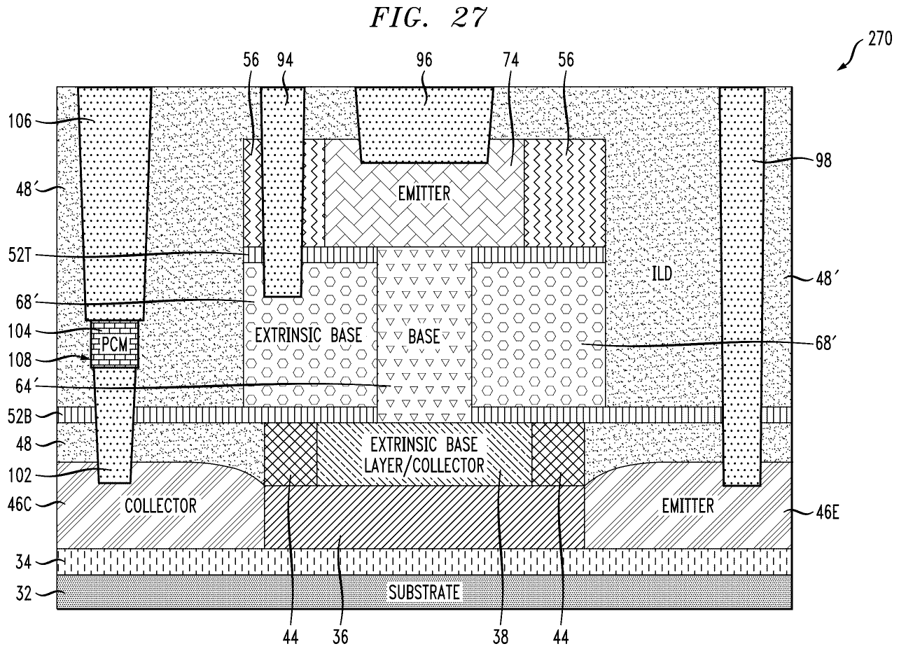

The portion of the contact opening within the ILD layer 48′ and above the bottom electrode 102 is widened. Phase change material such as GeSbTe (germanium-antimony-tellurium or GST) is deposited on the bottom electrode 102 and recessed to form a PCM layer 104. The PCM layer 104 will have a larger diameter than that of the bottom electrode 102 due to the previous widening of the contact opening. A structure 260 as shown in FIG. 26 is obtained at this stage of the process.

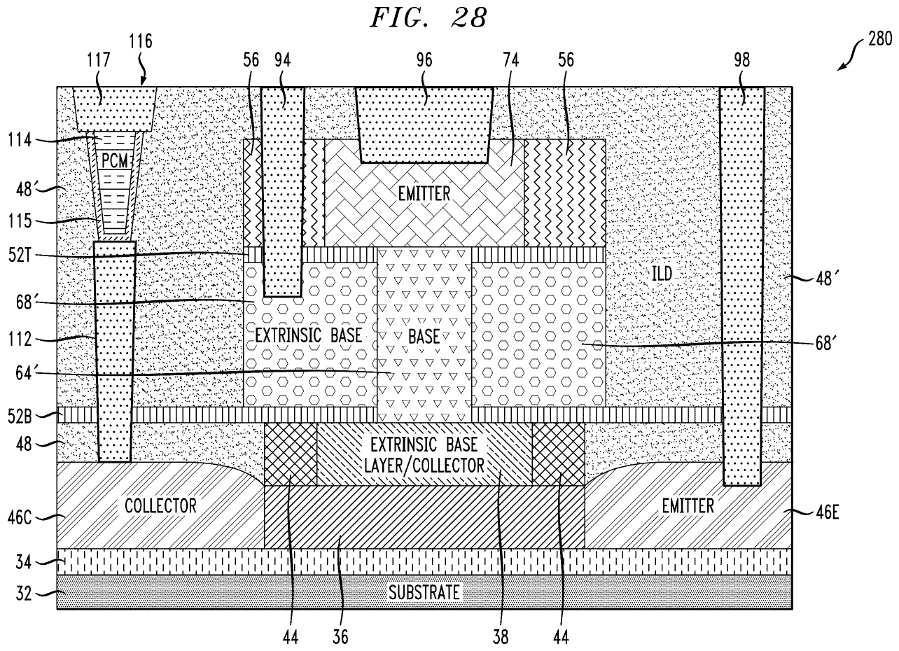

A PCM top electrode/contact 106 is formed on the PCM layer 104 to complete a PCM device 108 within the ILD layers 48, 48′. The PCM device 108 is electrically connected to the collector 46C of the lateral BJT. Contact openings and further contacts 94, 96, 98 corresponding to those described above with respect to FIG. 24 are formed in the structure 260. The electrode/contact 106 and the top contact 96 of the emitter of the vertical BJT are electrically connected, though such connection is outside the plane of the cross-sectional view of the resulting phase change memory cell 270 shown in FIG. 27.

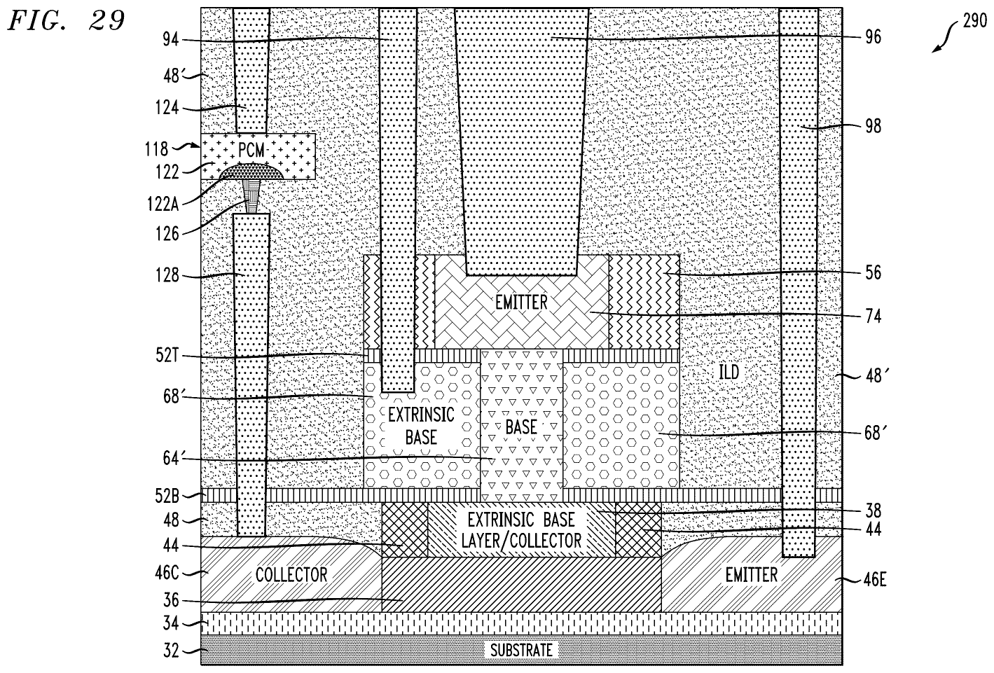

FIG. 28 schematically illustrates, in cross-section, a phase change memory cell 280 in accordance with a third exemplary embodiment of the invention. The structure includes a confined cell PCM device 116. The term “confined cell” refers to a general category of PCM cell, various types of which are known to the art. PCM cell structures include contact-minimized cells, which control the cross-section by the size of one of the electrodes, and volume-minimized or confined cells, which minimize the volume of phase-change material itself within the cell. A ‘mushroom’ cell as schematically illustrated in FIG. 29, in which the bottom electrode contact (often denoted ‘heater’) is the smallest element in the cell, is an example of a contact-minimized cell design.

Referring again to FIG. 28, a metal contact 112 extends between and electrically connects the collector 46C of the lateral BJT (also the emitter of the Sziklai Darlington transistor pair as discussed with respect to FIG. 1A and FIG. 1B) and the bottom electrode of the PCM device 116. The PCM device includes phase change material 114 within a metallic liner 115. This metallic liner may be deposited using CVD or ALD processes and is typically a thin film (2-5 nm) of either TaN or TiN. The PCM is also deposited via CVD or ALD processes to form a fill-in PCM structure. A top electrode/contact 117 of the PCM device 116 is electrically connected (not shown in FIG. 28) to the bit line (BL).

The exemplary phase change memory cell 290 schematically illustrated in FIG. 29 includes a Sziklai Darlington transistor pair that functions as the selector for a mushroom-type PCM device. The PCM device 118 includes a layer 122 of phase-change material between a top electrode 124 and a narrower bottom electrode (BE) 126. The PCM layer 122 includes a dome-shaped active region 122A that adjoins the bottom electrode 126. The PCM layer may comprise a chalcogenide alloy while the bottom electrode comprises an electrically conductive material such as TiN, TaN, W, WN or other suitable material(s). The top electrode further comprises a metal contact and extends between the PCM layer 122 and the top surface of the memory cell 290. Techniques for forming mushroom-type PCM devices are known to the art and further techniques may be developed. A bottom contact 128 extends between and electrically connects the bottom electrode 126 and the collector 46C of the lateral BJT. As discussed above, the collector of the lateral BJT is also the emitter of the Sziklai Darlington transistor pair comprising lateral and vertical BJTs. The bottom contact may comprise tungsten (W) or other suitable metal. The top contact 96 for the emitter 74 of the vertical BJT is electrically connected to the emitter top electrode/contact 124. As discussed above with respect to FIG. 1A and FIG. 1B, the terminals of the Darlington transistor pair are to be distinguished from the terminals of the bipolar junction transistors comprising the Darlington pair. For example, the collector of the Darlington transistor pair is the emitter of one of the transistors (here the lateral BJT) comprising the Darlington transistor pair and the emitter of the Darlington transistor pair is the emitter 74 of the vertical BJT and the collector 46C of the lateral BJT.

It is to be appreciated that the various layers and/or regions shown in the accompanying figures may not be drawn to scale. Furthermore, one or more layers of a type commonly used in such integrated circuit devices may not be explicitly shown in a given figure for ease of explanation. This does not imply that the layer(s) not explicitly shown are omitted in the actual integrated circuit device.

Given the discussion thus far, it will be appreciated that, in general terms, an exemplary memory cell includes a memory device comprising phase change material or, alternatively, a ReRAM device. A selector device within the memory cell includes a lateral bipolar junction transistor including an intrinsic base 36, an extrinsic base, a collector region 46C and an emitter region 46E, the collector region of the lateral bipolar junction transistor (also the emitter of the Darlington transistor pair) being electrically connected to the memory device. The selector device further includes a vertical bipolar junction transistor, the extrinsic base of the lateral bipolar junction transistor comprising a collector region of the vertical bipolar junction transistor, forming an extrinsic base/collector 38 as shown, for example, in FIG. 24, FIG. 27, FIG. 28 and FIG. 29. One of the lateral bipolar junction transistor and the vertical bipolar junction transistor is a PNP transistor while the other of the lateral bipolar junction transistor and the vertical bipolar junction transistor is an NPN transistor.

It will also be appreciated that an exemplary method for fabricating a memory cell includes forming a lateral bipolar junction transistor and a vertical bipolar junction transistor atop the lateral bipolar junction transistor, wherein the extrinsic base region of the lateral bipolar junction transistor forms the collector region of the vertical bipolar junction transistor. The exemplary method further includes forming a memory device electrically connected to the collector region of the lateral bipolar junction transistor (which is also the emitter of the Darlington transistor pair), wherein forming the memory device includes forming a bottom electrode, a top electrode, and phase change material between the bottom electrode and the top electrode. In one or more embodiments, forming the vertical bipolar junction transistor includes epitaxially growing base material on the extrinsic base region of the lateral bipolar junction transistor, growing a doped, extrinsic base layer on side walls of the base material, and growing a doped emitter region 74 on a top surface of the base material.

At least a portion of the techniques described above may be implemented in an integrated circuit. In forming integrated circuits, identical dies are typically fabricated in a repeated pattern on a surface of a semiconductor wafer. Each die includes a device described herein, and may include other structures and/or circuits. The individual dies are cut or diced from the wafer, then packaged as an integrated circuit. One skilled in the art would know how to dice wafers and package die to produce integrated circuits. Any of the exemplary devices illustrated in the accompanying figures, or portions thereof, may be part of an integrated circuit. Integrated circuits so manufactured are considered part of this disclosure.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having memory devices therein formed in accordance with one or more of the exemplary embodiments.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated.

The corresponding structures, materials, acts, and equivalents of means or step-plus-function elements, if any, in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A memory cell, comprising:
a memory device comprising phase change material; and
a selector device, the selector device comprising:
a lateral bipolar junction transistor including an intrinsic base, an extrinsic base, a collector region and an emitter region, the collector region of the lateral bipolar junction transistor being electrically connected to the memory device;
a vertical bipolar junction transistor, the extrinsic base of the lateral bipolar junction transistor comprising a collector region of the vertical bipolar junction transistor;
one of the lateral bipolar junction transistor and the vertical bipolar junction transistor being a PNP transistor, the other of the lateral bipolar junction transistor and the vertical bipolar junction transistor being an NPN transistor, the lateral bipolar junction transistor and the vertical bipolar junction transistor comprising a Sziklai Darlington transistor pair.

2. The memory cell of claim 1, wherein the memory device comprises a bottom electrode, a top electrode, the phase change material being positioned between the bottom electrode and the top electrode, the bottom electrode being electrically connected to the collector region of the lateral bipolar junction transistor.

3. The memory cell of claim 2, further including an interlevel dielectric layer, at least a portion of the vertical bipolar junction transistor being encased within the interlevel dielectric layer.

4. The memory cell of claim 3, further including:
a first dielectric layer extending over the interlevel dielectric layer, the bottom electrode being encased within the first dielectric layer;
a second dielectric layer extending over the first dielectric layer, the phase change material being encased within the second dielectric layer; and
a third dielectric layer extending over the second dielectric layer, the top electrode being encased within the third dielectric layer.

5. The memory cell of claim 4, further including a metal contact extending through the interlevel dielectric layer and electrically connecting the collector region of the lateral bipolar junction transistor with the bottom electrode.

6. The memory cell of claim 5, wherein the vertical contact opening includes a relatively narrow portion containing the bottom electrode and a relatively wide portion containing the phase change material.

7. The memory cell of claim 5, wherein the memory device is a confined cell phase change memory device.

8. The memory cell of claim 5, wherein the memory device is a mushroom-type phase change memory device.

9. The memory cell of claim 3, further including a vertical contact opening extending through the interlevel dielectric layer, the memory device being positioned within the vertical contact opening.

10. The memory cell of claim 1, wherein the vertical bipolar junction transistor comprises an emitter, further including a metal contact extending from the emitter of the vertical bipolar junction transistor, the metal contact being electrically connected to the emitter of the vertical bipolar junction transistor and the collector of the lateral bipolar junction transistor.

11. The memory cell of claim 10, further including:
a semiconductor substrate;
an electrically insulating layer between the semiconductor substrate and the lateral bipolar junction transistor;
a bottom dielectric spacer between the extrinsic base region of the lateral bipolar junction transistor and an extrinsic base region of the vertical bipolar junction transistor; and
a top dielectric spacer between the extrinsic base region of the vertical bipolar junction transistor and the emitter of the vertical bipolar junction transistor.

12. The memory cell of claim 11, wherein the lateral bipolar junction transistor comprises an intrinsic base region comprising silicon germanium, the extrinsic base region of the lateral bipolar junction transistor adjoining the intrinsic base region, the extrinsic base region of the lateral bipolar junction transistor having a higher doping concentration than the intrinsic base region.

13. A memory cell, comprising:
a memory device, the memory device comprising a phase change memory device or a resistive random access memory device; and
a selector device, the selector device comprising a lateral bipolar junction transistor and a vertical bipolar junction transistor configured as a Sziklai Darlington transistor pair, the lateral bipolar junction transistor comprising a collector region, the collector region of the lateral bipolar junction transistor being electrically connected to the memory device.

14. The memory cell of claim 13, wherein the memory device is a phase change memory device.

15. The memory cell of claim 14, wherein the lateral bipolar junction transistor comprises an extrinsic base, the extrinsic base of the lateral bipolar junction transistor comprising a collector region of the vertical bipolar junction transistor.

16. The memory cell of claim 15, further including:
an interlevel dielectric layer, at least a portion of the vertical bipolar junction transistor being encased within the interlevel dielectric layer;
a first dielectric layer extending over the interlevel dielectric layer;
a bottom electrode encased within the first dielectric layer;
a second dielectric layer extending over the first dielectric layer;
phase change material encased within the second dielectric layer;
a third dielectric layer extending over the second dielectric layer; and
a top electrode encased within the third dielectric layer, the memory device comprising the bottom electrode, the phase change material, and the top electrode.

17. A method of fabricating a memory cell, comprising:
forming a Sziklai Darlington transistor pair including a lateral bipolar junction transistor and a vertical bipolar junction transistor atop the lateral bipolar junction transistor, the lateral bipolar junction transistor comprising an emitter region, a collector region, an intrinsic base region, and an extrinsic base region adjoining the intrinsic base region, wherein the extrinsic base region of the lateral bipolar junction transistor comprises a collector region of the vertical bipolar junction transistor; and
forming a memory device electrically connected to the collector region of the lateral bipolar junction transistor.

18. The method of claim 17, wherein forming the Sziklai Darlington transistor pair includes:
epitaxially growing base material on the extrinsic base region of the lateral bipolar junction transistor;
growing a doped, extrinsic base layer on side walls of the base material; and
growing a doped emitter region on a top surface of the base material.

19. The method of claim 18, further including:
forming a metal contact on the collector region of the lateral bipolar junction transistor;
depositing phase change material over the metal contact; and
forming a top electrode over the phase change material.

20. The method of claim 19, further including:
forming a bottom spacer over the lateral bipolar junction transistor;
forming an interlevel dielectric layer over the bottom spacer;
forming a first dielectric layer over the interlevel dielectric layer;
forming a bottom electrode within the first dielectric layer;
forming a second dielectric layer over the first dielectric layer;
depositing the phase change material in an opening within the second dielectric layer;
forming a third dielectric layer over the second dielectric layer; and
forming the top electrode within the third dielectric layer.
